(19) United States
(12) Patent Application Publication
(10) Pub. No.: US 2024/0413256 A1
(43) Pub. Date: Dec. 12, 2024

(54) CURVED LAMINATED SOLAR PANEL AND METHOD OF MANUFACTURING THEREOF

(71) Applicant: APTERA MOTORS CORP., Carlsbad, CA (US)

(72) Inventors: Reed THURBER, San Diego, CA (US); Anuj M. THAKKAR, San Diego, CA (US); Nathan T. ENGLER, San Diego, CA (US); Jesse H. WOOD, San Diego, CA (US)

(73) Assignee: APTERA MOTORS CORP., Carlsbad, CA (US)

(21) Appl. No.: 18/806,656

(22) Filed: Aug. 15, 2024

Related U.S. Application Data
(63) Continuation-in-part of application No. 18/169,576, filed on Feb. 15, 2023.
(60) Provisional application No. 63/310,565, filed on Feb. 15, 2022.
(60) Provisional application No. 63/337,131, filed on May 1, 2022.
(60) Provisional application No. 63/345,419, filed on May 24, 2022.

(51) Int. Cl. H01L 31/048; H01L 31/05

(52) U.S. Cl. CPC H01L 31/0488; H01L 31/0481; H01L 31/0516

(57) ABSTRACT

The invention relates to an apparatus, system and method for a two-axis of curvature solar panel with doubly-curved solar cells. The solar panel comprises substrate and superstrate preforms having two-axis of curvature geometry and at least one rigid layer. The preforms may comprise one or more strengthened glass and/or polymer layers. A core comprising lower and upper encapsulant layers sandwiching a solar cell array is disposed between substrate and superstrate preforms forming a lamination stack. The solar cells may be tacked to the lower encapsulant layer. The preforms may be formed by flat lamination followed by thermoforming. The curved solar panel may comprise a flange suitable for assisting the assembly process and be made of materials with disparate mechanical and thermal properties. Aspects of the solar cells are recited that provide for the enabling double bendability of the cells within a doubly curved solar panel.

### CROSS-REFERENCE TO RELATED APPLICATIONS

This application claims priority to, and the benefit of co-pending U.S. Provisional Patent Application No. 63/310,565, filed on Feb. 15, 2022, entitled “Curved Laminated Solar Panel And Method Of Manufacturing Thereof,” U.S. Provisional Patent Application No. 63/337,131, filed on May 1, 2022, entitled “Doubly Curved Glass-based Solar Panel and Method of Manufacture Thereof,” U.S. Provisional Patent Application No. 63/345,419, filed on May 24, 2022, entitled “Curved Laminated Solar Panel with Improved Adhesion Layer and Method of Manufacture Thereof,” and U.S. patent application Ser. No. 18/169,576, filed on Feb. 15, 2023, entitled “Curved Laminated Solar Panel with Improved Adhesion Layer and Method of Manufacture Thereof,” each of which is incorporated by reference in its entirety.

### TECHNICAL FIELD

The present disclosure relates to an apparatus, system, and method for a laminated solar panel with two axes of curvature wherein the solar cells also have two axes of curvature.

### BACKGROUND

Conventional flat solar panels have been used in stationary terrestrial applications, such as remote buildings and communications towers, and later in factories, office buildings, solar farms and the like where the weight of the panel was of little or no consideration. Tempered glass has been used predominantly for the solar facing layer even with the associated disadvantages of increased weight, while resins and other polymers are substituted for such heavy tempered glass sheets in weight-sensitive, air or space applications, such as aeronautical applications, satellites and space exploration.

More recently the demand for mobile and shaped solar panels has generated interest in using both polymer and glass-based non-flat geometry solar panels. Such applications have dimensions and use requirements valuing light weight, durability and low cost of the non-flat geometry solar panel product. In the electric vehicle industry, intense research and development has occurred regarding solar-enabled body panels over the past several decades. Specifically, as solar panels are designed to provide a significant portion of the vehicle's energy, incorporating flat tempered glass solar panel constructions with thick-glass substrates and/or superstrates into the body of a solar electric vehicle has disadvantages of significant added weight that would limit its range and overall efficiency. It is therefore important to keep the solar panel as thin and light as possible. Often, a polymer layer or multi-layer stack is used instead of tempered glass to reduce weight. However, a multi-layer polymer laminate is complex and time-consuming to produce. Furthermore, typically used polymers, such as polyethylene terephthalate or PET, are subject to yellowing from UV radiation, low impact resistance, and/or bad sealing properties. To date these applications have been forced to choose between the durability of glass and the reduced weight of polymers.

In a non-planar or mold-based laminator, the laminates may be loaded into the lamination chamber as any combination of flat, flexible or preformed sheets. In addition, post lamination shaping can occur, as by, for example, vacuum forming or pressure forming. Using these techniques, shaped lamination of solar panels with two axes of curvature has been demonstrated. However, shaping of the solar cells in two dimensions has not due to techniques where a two-dimensional panel curvature has been accommodated by uniaxial bending of the solar cells.

Vehicle body panels typically have complex shapes and harsh environment operability and durability requirements. Manufacturing of solar panels having complex geometries is challenging for a variety of reasons, including damage or destruction of the delicate solar cells due to the conventional manufacturing process used. The primary reason for failure may be attributed to the normal and/or shear stresses caused by simple or complex bending, torsion, or other deformation within the solar cell, which exceeds the ultimate strength of the material, leading to immediate or premature failure. As a result, bending of solar cells to match complex panel shapes using conventional manufacturing processes has heretofore been difficult to achieve in a high-volume and/or high yield manner.

Other modes of failure may occur once the solar panel is in use. For example, exposure to the environment can cause defects or damage that reduce the solar panel's electrical output and longevity. A primary environmental risk factor is water ingress into and between the layers of the solar panel. Moisture can enter along the perimeter of the panel or through exposed polymer layers, such as polycarbonate, if present. Once moisture enters a laminated assembly, environmental thermal cycling, such as freeze-thaw cycles, may cause the layers to delaminate. Moisture can also cause damage to the solar cell materials, such as corrosion of the conductive contacts, oxidation of the silicon, or degradation of any anti-reflective coatings.

Another risk to solar panels arises from impacts to the solar panel from hail, rocks, and other foreign objects. A standard test for validating a solar panel's impact resistance is called the hail impact test, wherein a ball of ice, with a minimum diameter of about 25 mm (1 inch) is accelerated toward the surface of the panel, hitting it at approximately 23 m/s, or about 52 mph (see Ref. No. 61215, International Electrotechnical Commission (IEC)). A successful test will demonstrate no damage to the solar cell.

A third risk, specific to vehicular solar panels, is that the top layer is easily cracked, nicked and/or dented from airborne road debris (a scarring sometimes referred to as “road rash”), thereby reducing the visual appeal of the body panel. It is therefore advantageous to be able to choose the exterior layer of the solar panel based on expected environmental exposure.

The primary solar panel requirements for a solar-electric vehicle include high-efficiency, low-weight, high durability and reliability, and aesthetic shape. These requirements, in turn, dictate the choice of materials to be joined, the method of joining and the form-factor of the solar panel. Regarding the form factor, an aerodynamic and aesthetic body panel, such as a hood, roof or trunk, generally requires two axes of curvature. The doubly curved panel, in turn, generally requires doubly curved solar cells. Thus, the method of laminating or otherwise encapsulating the solar cells must provide for damage-free double bending of the cells. Finally, the materials of choice must provide for optical clarity for efficiency, water and moisture impermeability, resistance to impact, resistance to nicks, scratches and dents, and reliability under extreme environmental exposure, such as large temperature swings. To meet these requirements, the present invention provides two methods that may be varied for different body panels on the vehicle, for example: (1) in first approach, a substrate and/or superstrate material is a preformed, thermally or chemically strengthened glass; and (2) in the second, a substrate and/or superstrate material is a laminated and preformed polymer layer(s). A combination of the approaches is also considered.

Solar panel fabrication typically employs lamination to join or otherwise attach multiple layers of material necessary to the function and protection of the solar module. Most solar panel designs comprise at least two different polymer layers to achieve the necessary functionality, durability and reliability. Joining these layers is typically accomplished with a polymer adhesive; however, disadvantages exist as such polymers layers typically do not adhere well due to their dense, non-porous surfaces and low surface energy. Also, using polymer adhesives may lead to bubble formation through outgassing of the adhesive, or waviness in the surface due to the large thickness of the adhesive relative to at least one of the layers to be bonded. Furthermore, if multiple layers of adhesive such as POE are employed, multiple curing cycles and different POEs may be required to achieve an optimum curing state of the end product, thereby adding complexity and cost to the panel.

Thus, there is a need to improve interlayer adhesion, eliminate bubble formation, and/or waviness in the surface due to thick adhesive layers. Furthermore, there is a desire to move away from the precise cure profile of POE and other curable polymers so as to increase the yield and throughput of the preform lamination process. What is needed is a method of joining layers in a lamination stack wherein adhesion is improved, surface waviness is avoided, manufacturing is simplified, and time, energy consumption and cost are reduced. The present invention solves these problems by 1) cleaning and activating the surfaces to be joined with a plasma or corona treatment and 2) substituting a thin, pressure-sensitive adhesive, which may be processed at an ambient or reduced temperature, for the melt-processed polymer layer in the preforming step.

Within the electric vehicle, aeronautical and space industries, there is a need for a lightweight, highly durable, glass and/or polymer based solar panel with two-axes of curvature such as an aesthetically or aerodynamically shaped vehicle panel, wherein the solar cells themselves may also be bent along two axes.

### SUMMARY

The disclosed doubly curved solar panel comprises thin, thermally- or chemically-strengthened glass preforms with doubly curved solar cells therebetween. Alternatively, thin, single- or multi-layer polymer preforms may be substituted for one or both glass preforms in a doubly curved solar panel with doubly curved solar cells.

It is an object of the present disclosure to provide an apparatus, system and method for a laminated solar panel with doubly curved, durable, lightweight glass and/or polymer layers.

It is an object of the present disclosure to provide an apparatus, system and method for a laminated solar panel with doubly curved solar cells.

It is an object of the present disclosure to provide a solar panel with a structural flange for improved mating with the supporting structure, protection of the edge from environmental conditions, aesthetics including concealing of the edge, and ease of assembly with a supporting structure.

It is an object of the present disclosure to provide an apparatus, system and method for a laminated solar panel that has improved interlayer adhesion and is less susceptible to delamination.

It is an object of the present disclosure to provide an apparatus, system and method for a laminated solar panel having improved interlayer adhesion for reducing bubble formation and waviness in the surface thereof.

It is an object of the present disclosure to provide a method for incorporating a flow-melt adhesive layer in a laminated solar panel in a manner that avoids folds and wrinkles in said layer and cracks in the solar cells.

It is an object of the present disclosure to provide a solar panel that is compatible with automotive applications.

It is an object of the present disclosure to provide a solar panel that may be mass produced at low cost.

It is an object of the present disclosure to provide a system and method for producing a solar panel with the above properties. Other desirable features and characteristics will become apparent from the subsequent detailed description, the drawings, the abstract, and the claims, when considered in view of this summary.

### DESCRIPTION OF THE DRAWINGS

Non-limiting and non-exhaustive embodiments of the present disclosure are described with reference to the following drawings. In the drawings, like numerals describe like components throughout the several views.

For a better understanding of the present disclosure, reference will be made to the following Detailed Description, which is to be read in association with the accompanying drawings, which are incorporated in and constitute a part of this specification, show certain aspects of the subject matter disclosed herein and, together with the description, help explain some of the principles associated with the disclosed implementations, wherein:

FIG. 1A illustrates a perspective view of a glass-based, doubly curved solar panel with doubly curved solar cells, according to an embodiment of the present invention;

FIG. 1B illustrates an enlarged view taken from FIG. 1A of a glass-based, doubly curved solar panel with doubly curved solar cells, according to an embodiment of the present invention;

FIG. 2A illustrates a perspective view of a polymer-based, doubly curved solar panel with doubly curved solar cells, according to an embodiment of the present invention;

FIG. 2B illustrates an enlarged view taken from FIG. 2A of a polymer-based, doubly curved solar panel with doubly curved solar cells, according to an embodiment of the present invention;

FIG. 3 illustrates a perspective view of a doubly curved solar cell array, according to an embodiment of the present invention;

FIG. 4A illustrates a perspective view of a flanged, doubly curved solar panel with doubly curved solar cells, according to an embodiment of the present invention;

FIG. 4B illustrates a section view taken from FIG. 4A of a flanged, doubly curved solar panel with doubly curved solar cells, according to an embodiment of the present invention;

FIG. 4C illustrates an enlarged section view taken from FIG. 4B of a flanged, doubly curved solar panel with doubly curved solar cells, according to an embodiment of the present invention;

FIG. 5A illustrates a partially-exploded perspective view of a flanged solar panel and support structure, according to an embodiment of the present invention;

FIG. 5B illustrates a perspective view of an assembled flanged solar panel and support structure, according to an embodiment of the present invention;

FIG. 5C illustrates an enlarged section view taken from FIG. 5B of a flanged solar panel and support structure, according to an embodiment of the present invention;

FIG. 6A illustrates an exploded perspective view of exemplary substrate sheets prior to lamination, according to an embodiment of the present invention;

FIG. 6B illustrates a perspective view of exemplary substrate sheets after lamination, according to an embodiment of the present invention;

FIG. 6C illustrates a perspective view of exemplary substrate sheets after thermoforming, according to an embodiment of the present invention;

FIG. 7A illustrates a section view of a thick adhesive laminate, the adhesive laminate being thick relative to the protective layer, according to an embodiment of the present invention;

FIG. 7B illustrates a section view of an adhesive transfer tape laminate, according to an embodiment of the present invention;

FIG. 8 illustrates an expanded, perspective view of a doubly curved solar cell array laminate stack components of the present invention;

FIG. 9A illustrates a perspective view of laminate stack components prepared for alignment, according to an embodiment of the present invention;

FIG. 9B illustrates a perspective view of a solar cell array aligned to a substrate with a superstrate prepared for subsequent alignment, according to an embodiment of the present invention;

FIG. 9C illustrates a perspective view of a solar cell array and superstrate aligned to a substrate, according to an embodiment of the present invention;

FIG. 9D illustrates an enlarged plan view, taken from FIG. 9C, of a solar cell array and superstrate aligned to a substrate, according to an embodiment of the present invention;

FIG. 10A illustrates a perspective view of a layer of encapsulant having relief cuts, according to an embodiment of the present invention;

FIG. 10B illustrates a perspective view of a layer of encapsulant having relief cuts after draping onto a substrate, wherein the substrate is omitted for clarity, according to an embodiment of the present invention.

FIG. 11 illustrates a flowchart for fabrication of a glass and/or polymer-based, doubly curved solar panel with doubly curved solar cells, according to an embodiment of the present invention;

FIG. 12A illustrates a section view of a doubly curved solar panel wherein the solar cells are flat, according to an embodiment of the present invention; and

FIG. 12B illustrates a section view of a doubly curved solar panel wherein the solar cells are curved, according to an embodiment of the present invention.

### DETAILED DESCRIPTION

Non-limiting embodiments of the invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention according to the present disclosure, and are not to be considered as a limitation thereto.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

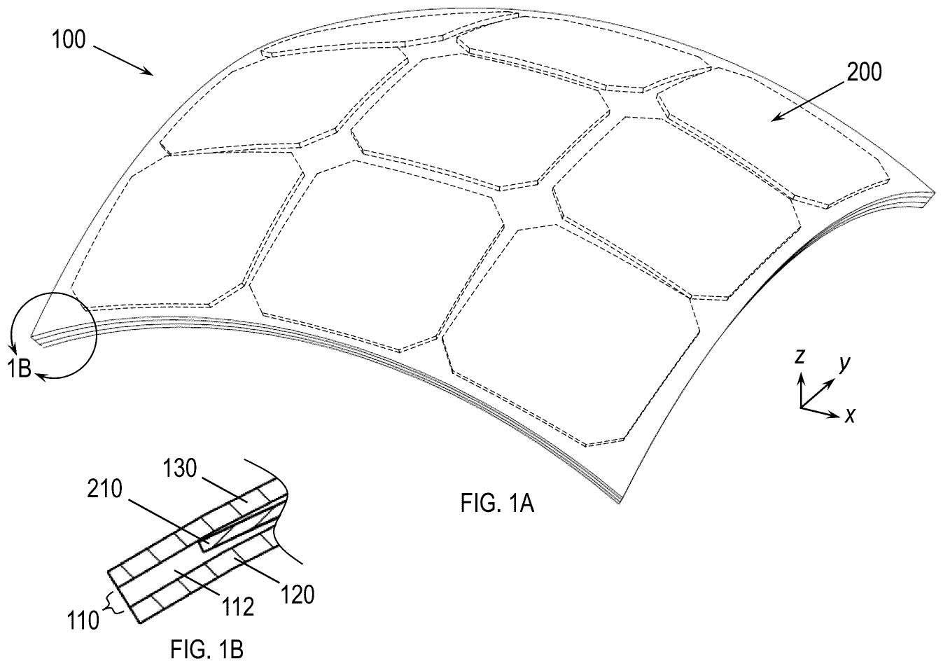

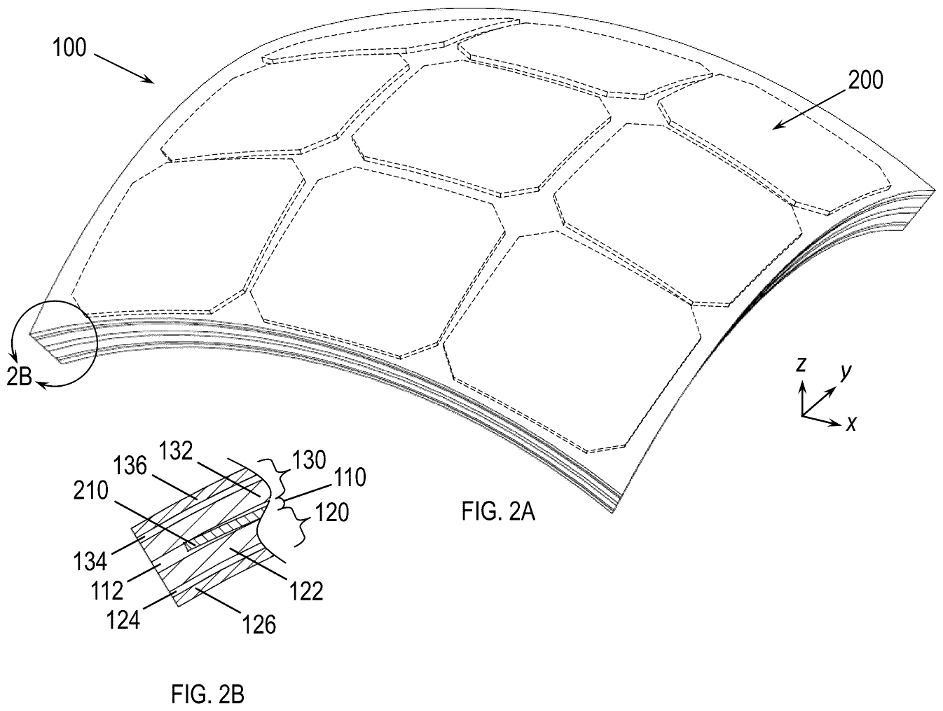

The drawings, including FIGS. 1A, 1B, 2A and 2B, may contain sizes and shapes of respective portions that are appropriately exaggerated for ease of understanding. Therefore, the comparative sizes and/or shapes displayed in the drawings should be considered non-limiting.

The presently disclosed solution to the challenges described above is to use thin, rigid preforms to gently and uniformly bend the solar cell(s) along two orthogonal directions. The preforms may comprise single or multiple layers wherein at least one layer is rigid. The preforms may be made of a glass or a polymer, or a combination thereof, depending on the environmental exposure in the end-use application. A flexible adhesive layer is used to encapsulate the solar cells and bond the preforms.

In a first approach, thermally or chemically strengthened glass is used to sandwich the solar cells in a single or doubly curved solar panel. Thermally or chemically strengthened glass is more resistant to impacts, nicks and dents, is more optically transmissive, is immune to yellowing over time, and, in the case of tempered glass, may be more cost-effective than polymer materials. However, when producing a shaped glass solar panel the strengthening process must be carried out after the preforming process.

In a second approach, one or more polymer layers are used as the preform. Polymer layers can also be resistant to impacts, nicks and dents. However, some polymers, such as polycarbonate, are subject to yellowing over time and require special processing or protection to improve their stability, such as yellowing inhibitors or ultraviolet absorption layers. A combination of glass and polymer preforms may be used where appropriate to obtain the advantages of each material.

In a first embodiment, illustrated in FIGS. 1A and 1B, a laminated solar panel 100 comprises a solar cell array 200 encapsulated in a polymer adhesive 112 and disposed between a pair of preformed, thin, strengthened glass layers 120, 130. The solar panel may be curved about two axes, x and y. The radii of curvature about each axis, Rₚₓ and R_{py}, in one or more portions of the panel are such that the cells 210 of the solar cell array 200 must bend in two directions. The local radii of curvature of any portion of the panel 100 may be equal or different in magnitude and/or sign. The laminate, shown in the detail view of FIG. 1B, includes a pair of glass layers which serve a plurality of purposes for the structure and function of the solar panel 100. At the bottom is a substrate 120 comprised of rigid, ultra-thin, chemically strengthened, alkali-aluminosilicate glass, such as Gorilla® glass from Corning, Dragontail® from Asahi, or Xensation® from Schott, that provides mechanical stiffness. At the top is a superstrate 130 comprised of a rigid layer of ultra-thin, thermally or chemically strengthened glass that provides mechanical stiffness, resistance to impact, resistance to abrasion, and a barrier against moisture. In the center may be a core 110 comprising the cells 210 of the solar cell array 200 surrounded by a layer of flow-melt adhesive, such as polyolefin elastomers (POE) 112. The POE 112 acts as a barrier to water ingress and increases durability and reliability.

While it is important to protect the entire panel against moisture ingress, the perimeter of the panel where the layer interfaces are exposed may be especially vulnerable. Such exposure can lead to delamination and failure of the solar cells. Therefore, it is important to incorporate protective edging in the panel design, examples of which are given later in this disclosure.

In a second embodiment, illustrated in FIGS. 2A and 2B, a laminated solar panel 100 comprises a solar cell array 200 encased in a plurality of polymer layers. The solar panel may be curved about two axes, x and y. The radii of curvature about each axis, Rₚₓ and R_{py}, in one or more portions of the panel are such that the cells 210 of the solar cell array 200 must bend in two directions. The local radii of curvature of any portion of the panel 100 may be equal or different in magnitude and/or sign. The lamination, shown in the detail view of FIG. 2B, includes a plurality of polymer layers which serve a variety of purposes for the structure and function of the solar panel 100. At the bottom is a substrate 120 which includes one or more polymer layers that provide mechanical stiffness and a seal against water ingress. In this example, the substrate 120 comprises a flexible layer of ethylene tetrafluoroethylene (ETFE) 126, a flexible adhesive layer 124, and a rigid layer of polycarbonate (PC) 122. At the top is a superstrate 130 which includes one or more polymer layers that provide mechanical stiffness, a seal against moisture, and resistance to damage caused by impact. In this embodiment, the superstrate 130 comprises a rigid layer of PC 132, a flexible adhesive layer 134, and a flexible layer of ETFE 136. In general, the PC 122, 132 may be configured to provide mechanical stiffness and impact resistance; while the ETFE 126, 136 acts as a barrier to water ingress, reduces dirt accumulation and provides scratch resistance. In the center may be a core 110 comprising the cells 210 of the solar cell array 200 surrounded by a layer of flow-melt adhesive, such as polyolefin elastomers (POE) 112. The POE 112 acts as a barrier to water ingress and increases durability and reliability.

In a third embodiment, the solar panel may comprise both glass and polymer preforms with a polymer substrate and glass superstrate or vice versa. This configuration may have a cost advantage, as in the case of chemically strengthened glass, which is generally more expensive than polymer laminates.

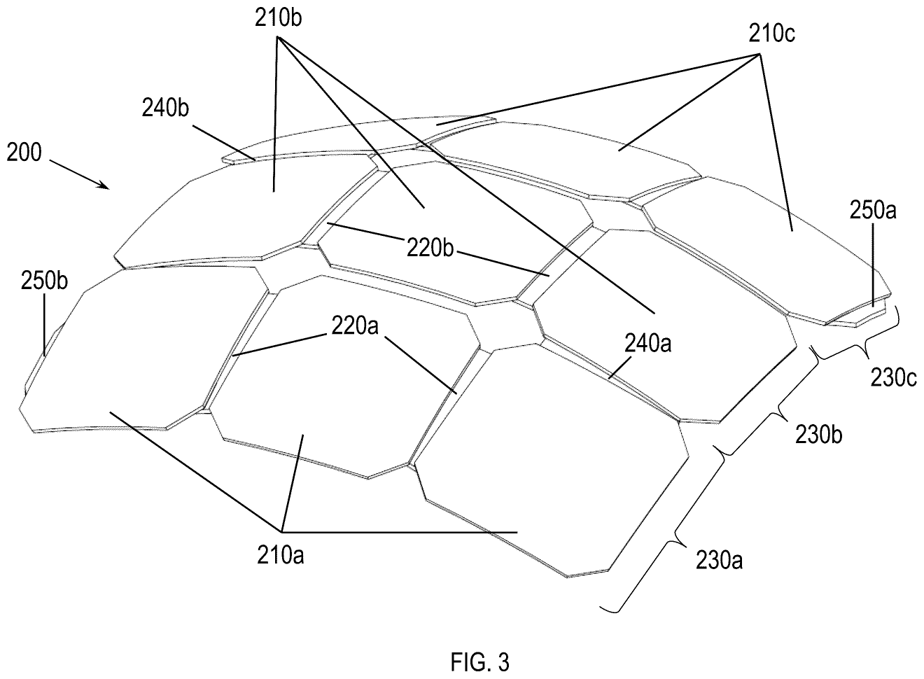

The core 110 of the solar panel 100 may comprise a solar cell array 200, as depicted in FIG. 3. The array 200 may comprise individual solar cells arranged in rows 230a, 230b, and 230c. In a first row 230a, individual cells 210a may be electrically connected by intra-row interconnects 220a, which may be soldered to the back side of the cells 210a, 210b, and 210c. Second 230b and third 230c rows may be similarly electrically connected via intra-row interconnect 220b, and 220c, respectively. The rows 230a, 230b, and 230c may be further electrically connected to form a serpentine pattern by inter-row interconnects 240a and 240b. Alternatively, other series or parallel interconnect patterns may be used, depending on the application, and the 3×3 array 200 as shown in FIG. 3 is exemplary and being used to convey general arrangements. Termination interconnects 250a, 250b may be located at the end of the first 230a and last 230c rows.

The laminate layers may be chosen from a large variety of materials. A single-layer substrate or superstrate may be made of thermally or chemically strengthened glass. The advantage of thermally strengthened glass, also known as tempered glass, is that it is lower cost than chemically strengthened glass. Due to the parabolic stress profile that must be generated across its thickness to create tempered glass, however, it has a thickness range of about 2 to greater than about 20 mm. The advantage of chemically strengthened is that it can be made much thinner and achieve the same strength as tempered glass. By way of example, Gorilla® glass is available from the manufacturer in thicknesses of 0.4-2.0 mm. Almost all projects, however, are confined to four standard thicknesses, i.e. 0.55, 0.7, 1.1 and 1.8 mm. Putting these parameters in an automotive context, a thicker piece of glass is warranted in areas where impact from sharp objects, such as rocks and stones, is likely to happen, such as a hood panel. In areas of lower impact and less risk of abrasion from road debris, a thinner piece of glass could be used to save overall weight. Typical examples of the latter would be the roof and trunk or hatch panels.

For the polymer layers, non-limiting alternatives for PC include polypropylene (PP), poly (methyl methacrylate) (PMMA), polyethylene terephthalate (PET), polyvinylchloride (PVC), polyethylene (PE), cyclic olefin copolymer (COC), and Fluorinated ethylene propylene (FEP). Non-limiting alternatives for POE include polyolefin (PO), crossing-linking polyolefin (XPO), polyvinyl butyral (PVB), thermoplastic olefin (TPO), ethylene-vinyl acetate (EVA), silicone, polyvinylidene difluoride (PVDF), and thermoplastic polyurethane (TPU). And non-limiting alternatives for ETFE include glass and ethylene chlorotrifluoroethylene (ECTFE).

The polymer layers may be chosen to have a wide range of thicknesses. The thickness of the ETFE layer, for example, may be typically chosen within the range of 0.01-0.2 mm, with some applications using slightly thicker values. The thickness of the POE layer, for example, may be typically chosen within the range of 0.1-2 mm, with some applications using up to 110 mm. The thickness of the PC layer, for example, may be typically chosen within the range of 0.25-13 mm, with some applications using slightly thicker values. Also, the laminated stack may have different thicknesses for the layers both above and below the solar cells. For example, the superstrate may have a thicker dimension than the substrate. Where weight is a consideration, such as in a high efficiency solar vehicle design, an asymmetric laminate stack can advantageously reduce weight by, for example, reducing the thickness of the substrate relative to the superstrate. In addition, a thicker superstrate relative to the substrate may provide advantages for the impact resistance and longevity of the solar panel.

The polymer layers may be chosen to have a wide range of elastic modulus. For example, ETFE may have an elastic modulus of 0.490-0.827 GPa, while PC may have an elastic modulus of 1.79-3.24 GPa. In the present disclosure, forming of one or more rigid (high modulus) polymer layer(s), such as PC, occurs prior to lamination. However, for the ETFE, because it is generally thin and flexible, handling of a formed sheet becomes difficult. This problem is solved by first bonding an ultra-thin layer of ETFE to a thicker, stiffer polymer layer, such as PC, prior to forming. The laminate may be bonded using one of several methods, including flatbed lamination, roll lamination, or evacuated chamber lamination. Once supported in this manner, the ETFE may elongate without breaking and can be more easily handled after forming.

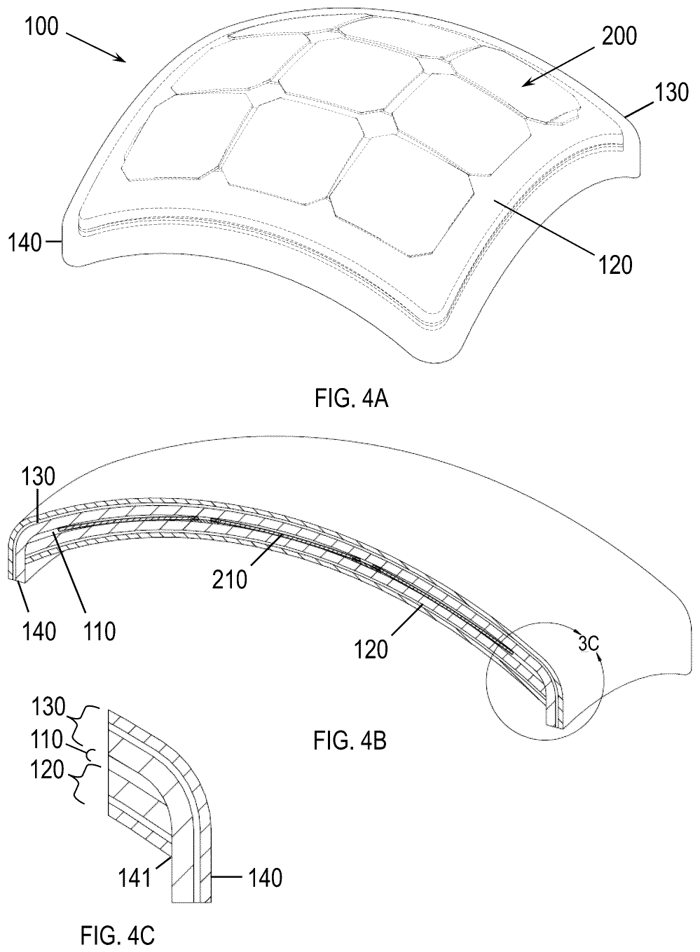

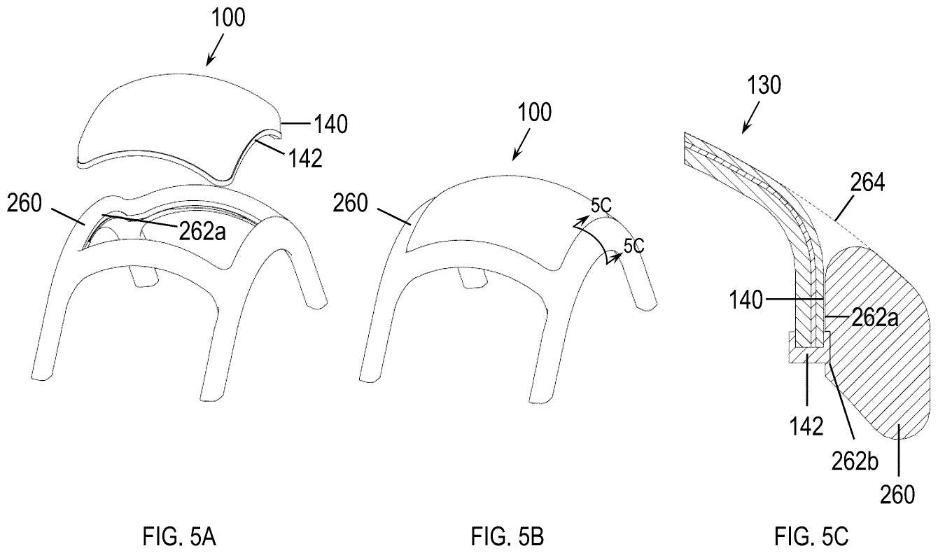

In an alternate embodiment, displayed in FIGS. 4A-4C, a laminated solar panel 100 may include a structural flange 140 comprising all or a portion of the laminated layers. In FIGS. 4B and 4C for example, only the one or more layers of the superstrate 130 form the flange 140, while the core 100 and substrate 120 are terminated by the superstrate flange 140 at an interface 141. A seal against water ingress and delamination for the core 110 and substrate 120 is thus integrally formed. The flange 140 may serve several functions, as exemplified in FIGS. 5A-5C. In a first function, illustrated in FIG. 5A, the vertical flange 140 may be used as an alignment feature for ease of assembly to the vertical surface 262a of a support structure 260, such as the frame of an automobile. In FIG. 5B the panel 100 has been mated to the frame 260 through a vertical motion. FIG. 5C illustrates the mated interface which provides a small gap between the flange 140 and frame datum 262a suitable for containing a structural adhesive. Alternative ways of attachment are possible, such as a notch 262b in the frame 260 which accepts the panel edging 142, thereby providing a snap fit retainment feature. Also, the flange 140 may be used to partially protect the edge of the laminated panel by positioning it toward the interior of the supporting structure 260, in this case a vehicle, and away from exposure to the elements. The panel edging 142, which is the primary way of protecting the panel edge, may comprise a layer of sealant/adhesive, or a rubber or metal seal, or any combination thereof. The flange may also serve aesthetic purposes, such as hiding the edge of the panel from view and thus hiding any edge sealing elements from the viewable surface. Furthermore, the panel edge termination (outer fillet of the flange) used to form an aesthetic seam with the frame 260 as by, for example, forming a fillet-to-fillet joint along an extension of the panel contour 264.

Another aspect of the present invention is the preforming of substrate and superstrate layers prior to final solar panel lamination. This is especially true of glass materials wherein the strengthening process, either thermal or chemical, must be applied to the final form factor. Preforming of glass is typically achieved through drape forming or press bending.

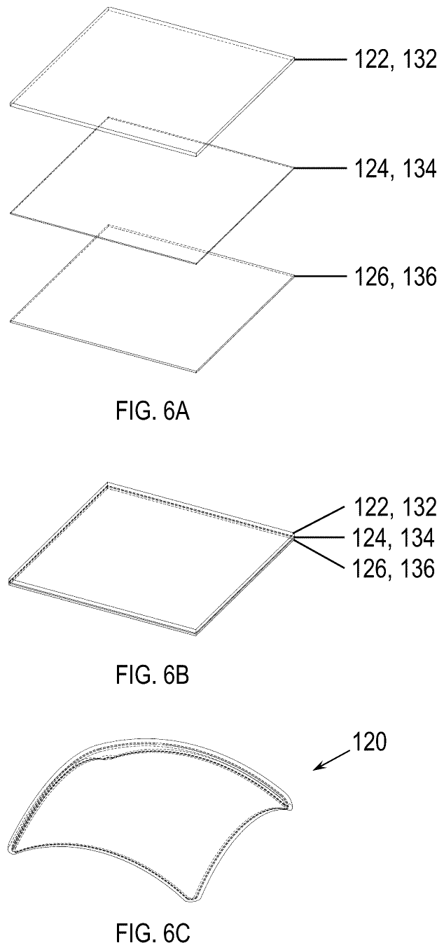

Polymer preforming, on the other hand, is more complex due to several considerations best illustrated by example. In FIG. 6A, the substrate 120 and superstrate 130 comprise a rigid layer of PC 122 132, a flexible adhesive 124 134 and a flexible layer of ETFE 126 136. In this example the flexible adhesive is POE. Exemplary layer thicknesses are as follows:
ETFE (0.050 mm).
POE (0.075 mm)
PC (1 mm)

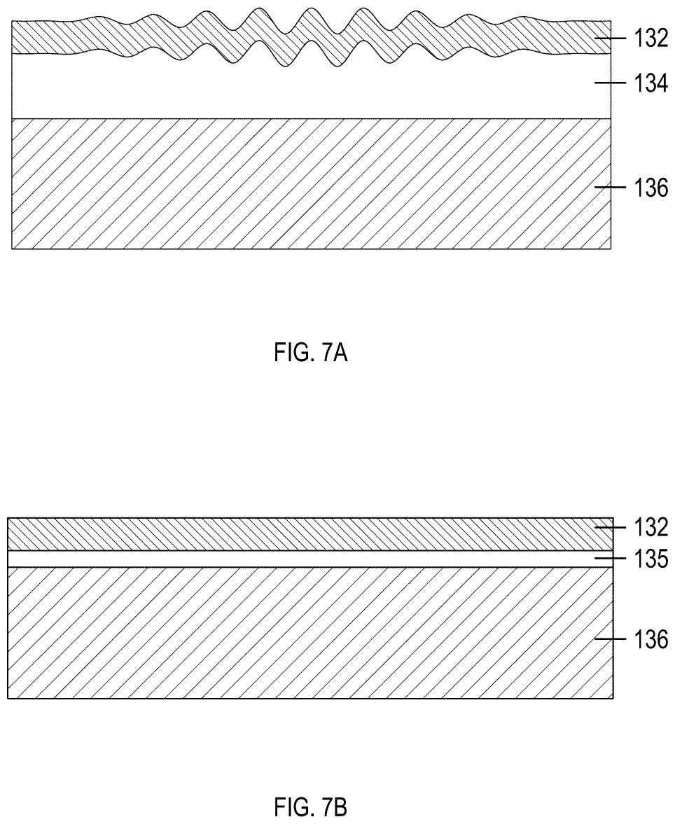

Because ultra-thin (0.050 mm) ETFE is difficult to handle as a free-standing cut sheet and difficult to form without wrinkles, the first preform fabrication step is to dispose the ETFE on a more rigid substrate, in this case a PC layer. To avoid handling free-standing sheets, the flexible adhesive 124 134 and ETFE 126 136 are dispensed from rolls onto rigid, cut sheets PC 122 132, as depicted in FIG. 6B. Another reason for using a roll-to-roll or roll-to-cut sheet process is to minimize the possibility of trapping air between the layers. In a second preform fabrication step, a lamination process is used to soften the POE 124 134 for bonding the PC122 132 and ETFE126 136. This may be achieved through a roll or flatbed laminator. However, both the POE 124 134 and ETFE126 136 layers are very flexible. During the flat lamination process the POE 124 134 melts and becomes a viscous fluid. This may allow the ETFE 126 136 to buckle and flex resulting in a wavy surface. This is exacerbated by the fact that the POE layer 124, 134 is thicker than the ETFE 126, 136 layer. FIG. 7A shows the post flat lamination of the exemplary layers (PC 136, POE 134, ETFE 132) wherein the thickness and melt processing of the POE 134 have given rise to surface waviness in the ETFE 132. In a third step, the flat laminate may be pre-formed to the desired body panel shape, as by, for example, vacuum forming (generally known as thermoforming), pressure forming or drape forming, as shown in FIG. 6C. In a fourth step (not shown), the preform may be trimmed to the final outer dimensions.

To overcome the issue with ETFE waviness and/or wrinkling, a new approach is needed. In an exemplary embodiment of the present invention, the adhesive layer may comprise an acrylic- or silicone-based adhesive transfer tape (ATT), such as, for example, is manufactured by 3M™ under product numbers PSA468MP, PSA467MP, or GT580NF. In the present embodiment the layer thicknesses are as follows:
ETFE (0.050 mm).
ATT (0.025 mm)
PC (1 mm)

In contrast to the POE layer of the previous example, the thickness of the ATT is only half the thickness of the ETFE layer and it does not flow during the lamination process. Consequently, there is less chance for the ETFE layer to buckle and flex, thereby ensuring a smooth surface. FIG. 7B shows the post flat lamination of the exemplary embodiment layers (PC 136, ATT 135, ETFE 132) wherein the reduced thickness and non-melt processing of the ATT maintain the ETFE 132 planarity. In this way, substituting ATT for a flow-melt adhesive improves the process and quality of the resulting panel.

As with a flow-melt adhesive, the process for applying ATT begins with the tape in roller form. This is necessary because, once the protective backing has been removed from the tape, the remaining adhesive presents as a flexible tacky film and is difficult to handle in cut-sheet form—in contrast to POE, which only becomes tacky upon sufficient heating and may therefore be handled in sheet form. To avoid handling free-standing sheets, the flexible ATT 125, 135 and ETFE 126, 136 may be dispensed from rolls onto rigid, cut sheets PC 122, 132. As before, another reason to use a roll-to-roll or roll-to-cut sheet process is to minimize the possibility of trapping air between the layers.

In a roller-based process the sheets to be laminated are disposed on feeder rolls, which are then simultaneously paid off into a pair of pinch rollers. The pinch rollers pull the layers off the feeder rolls while simultaneously bonding them together using pressure and heat. In the case of the POE adhesive (curing temperature of between about 150° C. and 155° C.), both the pressure and the heat are necessary for bonding to occur. Furthermore, the pull rate and temperature of the rollers must be carefully controlled in order to form a proper bond line and leave the POE in a partially cured state. The combination of precise and uniform cure temperature and precise cure time is difficult to achieve, especially over large sheet and roller widths. By contrast, in the adhesive tape case only pressure is necessary. Thus, the lamination process may be made independent of roller speed and higher throughput may be achieved. In some cases, a small amount of heat may still be desirable. This is termed “heat-assisted bonding” and generally occurs at around 80-90° C. While the application of heat to the films through the rollers may require a reduction in feed rate relative to pressure-only bonding, because the acrylic-based tape material does not flow there is little risk of inducing waviness with an excess of heat. This keeps the process window open and allows for greater throughput relative to the flowable polymer (e.g. POE) case.

The use of ATT provides several advantages which may be classified into manufacturing and performance advantages. Functionally, the invention may be thought of as substituting only a minimum pressure for a precision combination of heat and pressure as it relates to the adhesion process. Thus, a first manufacturing advantage is the reduction or elimination of the thermal load required for preform lamination. A second advantage comes from the larger process window of the adhesive tape material, which results in improved control of the preform lamination process (rollers need not be heated, lamination rate may be non-critical). The increased throughput possible with adhesive tape leads to a reduced cycle time for laminated preforms, comprising a third advantage. Finally, the lower energy cost, improved yield and lower cycle time may contribute directly to a lower component cost, a fourth distinct advantage.

First, an advantageous and improved appearance of the final laminated panel may be related to the increased surface smoothness due to the reduced adhesive thickness and non-melt processing. Second, the reliability may be improved through improved adhesion (better peel strength). Third, the reliability may be improved through a reduced bond line forming a smaller opening for moisture ingress. A yield advantage arises from the reduced or eliminated bubble formation from outgassing of the POE layer. And an additional performance advantage comes from the improved optical transmission of the adhesive tape relative to the POE layer.

While ATT has many advantages, it also has some disadvantages, such as the lack of ultraviolet (UV) radiation absorption and poor moisture protection. However, these disadvantages may be mitigated to a large degree through the use of additional moisture and/or UV protections in the laminate stack. In the case of moisture ingress, the ETFE provides sufficient protection from the environment, while the panel edge may be protected first by the ultra-thin bond line provided by the adhesive tape (25 μm), and second by an edge seal or potting during assembly. In the case of UV radiation, which is necessary for the protection of the PC layer, other materials in the laminate stack may be hardened against it, such as the ETFE layer, or the PC layer itself. This may be achieved through additives at the extrusion level or coatings applied after extrusion. Thus, the advantages of the present apparatus, system and method may be made to outweigh the disadvantages.

Throughout the solar panel fabrication process, one or more laminate surfaces may be subject to an adhesion promotion step. Many plastics have chemically inert and nonporous surfaces with low surface energy causing them to be non-receptive to bonding with adhesives. For these materials surface treating, such as with an atmospheric plasma or corona, may be used to improve adhesion by increasing the surface energy through the creation of dangling chemical bonds. In one example pertaining to the polymer flat lamination, one side of the ETFE is pretreated in the material extrusion process (i.e. at the ETFE manufacturer) and is present in the incoming material. In the flat lamination process, the treated side of the material is oriented toward, and promotes adhesion with, the transfer tape. In an exemplary embodiment of the present invention, during the process of assembling the lamination stack, the top side of the polymer substrate and the bottom side of the polymer superstrate are cleaned and then treated with an atmospheric plasma or corona to improve adhesion with the POE encapsulant. Glass substrates and/or superstrates, by contrast, are typically not surface treated after cleaning.

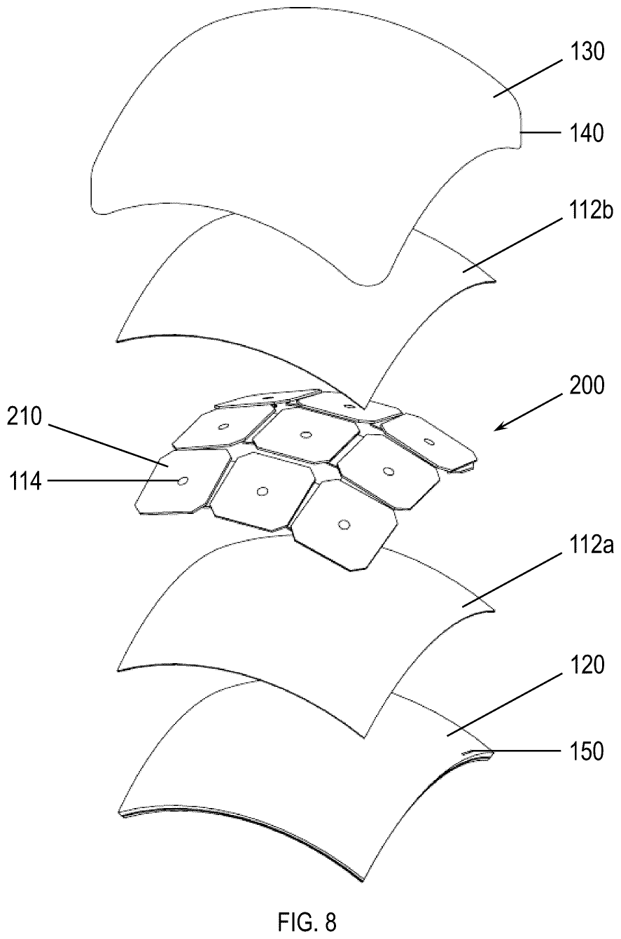

Referring to FIG. 8, the substrate preform 120 presents a convex surface upon which the array of cells 200 may be placed. A first layer of POE 112a may be disposed on the substrate 120. This layer may be flexible and may be trimmed to conform to the shape of the substrate 120 without inducing folds. The solar cell array 200 may be placed on the surface of the POE 112a as a flexible subassembly and it may partially conform to the surface of the substrate/POE 120/112a subassembly; that is, the center of each cell may be approximately tangent to the surface normal of the convex POE 112a. An amount of heat sufficient to soften the POE material 112a may be applied to the center of each solar cell 114. The heat may be applied by the flow of heated air or other gas, or by other conductive, convective, or radiative heating element. The softened POE layer 112a may be rendered tacky and thereby adhere to each cell 210 in the array 200 forming a tack 114. The tacks 114 may serve the purpose of maintaining the position of the cells 210 throughout subsequent assembly and lamination operations. The remaining assembly operations may include disposing a second layer of POE 112b on the solar cell array 200, followed by disposition of the superstrate preform 130 on the second layer of POE 112b. The conformal contact of the second POE layer 112b and the gravitational pressure applied by the superstrate 130 may further serve to maintain the positions of the cells 210 in the array, for example, by preventing rotation about the tacks 114. The complete stack may then be loaded into a laminator and laminated 174.

In an alternate embodiment, the laminate stack may be assembled in a concave orientation. Here, the superstrate 130 would appear at the bottom, followed by the core layers 112b, 200, 112a, and the substrate 120. In this exemplary process, the superstrate and first encapsulant 112b present a concave surface upon which the array of cells 200 may be placed. The solar cell array 200 may be placed on the surface of the encapsulant 112b as a flexible subassembly and may partially conform to the surface thereof; that is, only three or four corners of each cell may contact the encapsulant 112b. An amount of heat sufficient to soften the encapsulant material may be applied to at least one corner of each solar cell 114. Advantageously, in a regular array, up to four cells may be tacked at once in an area where the cells are proximate to each other. The remaining assembly and lamination steps may comport with the steps previously described with respect to the convex assembly.

Another aspect of the present invention may include the use of fiducials-alignment features or datums to facilitate proper alignment of the layers forming the lamination stack.

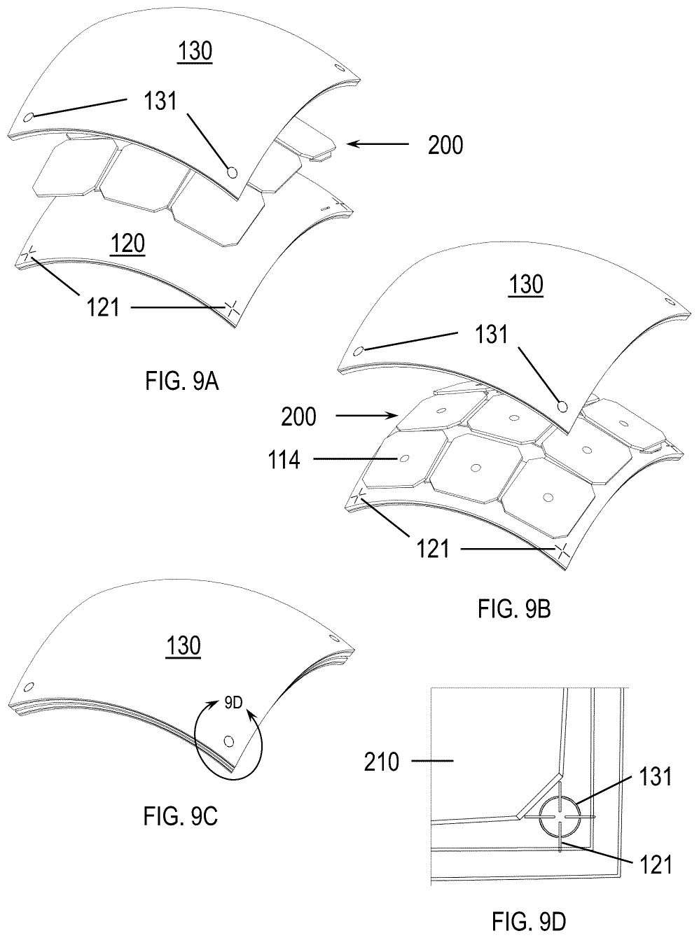

Fiducials may take the form of visual alignment indicators disposed on two or more surfaces of the layers forming the lamination stack, which may aid in manual or robotic alignment thereof. Alignment features may take the form of apertures or openings in one or more layers of the lamination stack, through which alignment rods, pins, etc., may pass. Datums may take the forms of edge features of the stack, such as a corner or jut-out, which may be temporarily aligned through a complementary abutment formed in the laminator. Fiducials may be utilized on any of the subcomponents, and surfaces thereof, as exemplified in FIGS. 9A-9D. In FIG. 9A, the laminate stack is illustrated in unassembled component form comprising substrate 120, solar cell array 200, and superstrate 130. Encapsulant layers have been omitted for clarity. Alignment marks 121 may be printed, or otherwise marked, on the substrate 120—in this case in the corners. In a first alignment, the solar cell array 200 may be aligned to the substrate 120, as shown in FIG. 9B, and subsequently tacked 114 in place at the centers of the cells 210. Alignment marks may be critical in this step when there are no other practical datums available. While manual alignment is possible, a preferred method may be the use of machine vision to guide a robotic placement of the array. For the latter approach, machine readable fiducials may be beneficial. In a second alignment, indicated in FIG. 9C, the superstrate 130 may be aligned to the substrate 120. For this step, complimentary alignment marks 131 may be printed, or otherwise marked, on the superstrate 130, also in the corners. The resulting aligned fiducials and layers may be seen in the enlarged view of FIG. 9D, where an aligned solar cell 210 touches the substrate cross 121 at its corners. Also visible, the superstrate fiducial 131 may be symmetrically juxtaposed over the substrate fiducial 121. Since at this point, significant gaps remain between the layers, due to the flat solar cells 210, and viewing the fiducials from the local surface normal may produce parallax-induced misalignment. Therefore, it may be preferred that the exemplified fiducials be viewed from vertical position parallel to the axis of assembly for proper alignment. Alternative viewing angles may be used provided that parallax and thermoforming distortion are taken into account.

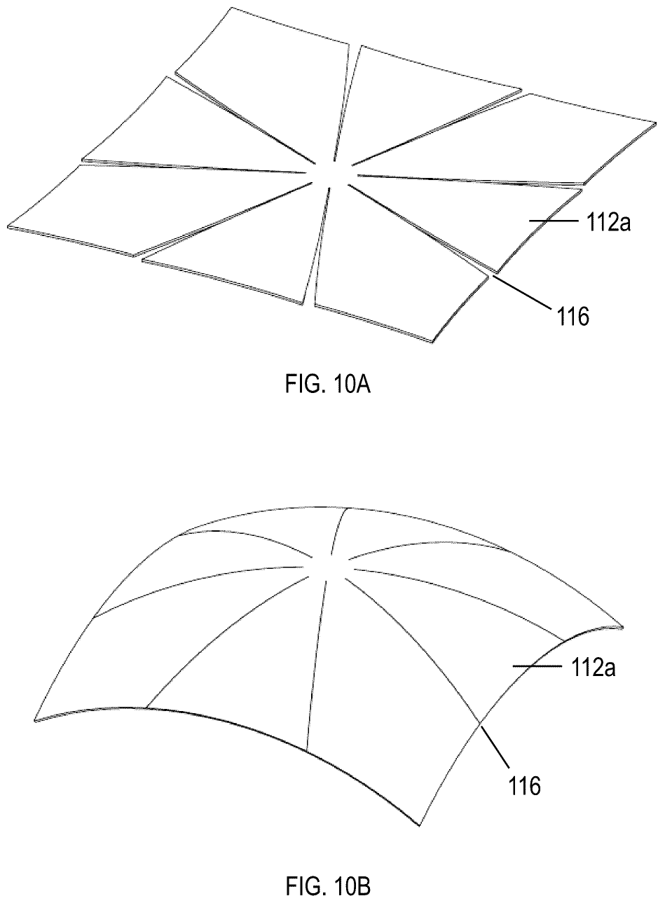

Another aspect of the present invention involves managing sheets of encapsulant material during the laminate stack assembly process. During the core assembly portion of the latter, a first, flexible sheet of encapsulant material 112a may be draped over the convex substrate preform 120, as shown in FIG. 8. As the draped sheet 112a conforms to the doubly curved surface of the substrate preform 120, excess material gathers into folds which may serve to trap air or apply excess localized pressure on a cell 210 of the solar cell array 200. A means of mitigating this lamination hazard is given in FIGS. 10A and 10B. While still in sheet form, cuts 116 are made in the encapsulant layer 112a thereby forming gaps in the sheet, as shown in FIG. 10A. The cuts 116 are shaped such that when the layer 112a it is draped over the substrate preform 120 the cuts 116 rejoin and the gaps disappear, as shown in FIG. 10B. In this way folds in the encapsulant layer 112a may be reduced or eliminated. A similar approach may be employed to avoid folds in the second, flexible sheet of encapsulant material 112b, as in FIG. 8, as it is draped over the solar cell array 200, which, in turn, has been placed over the first encapsulant layer 112a.

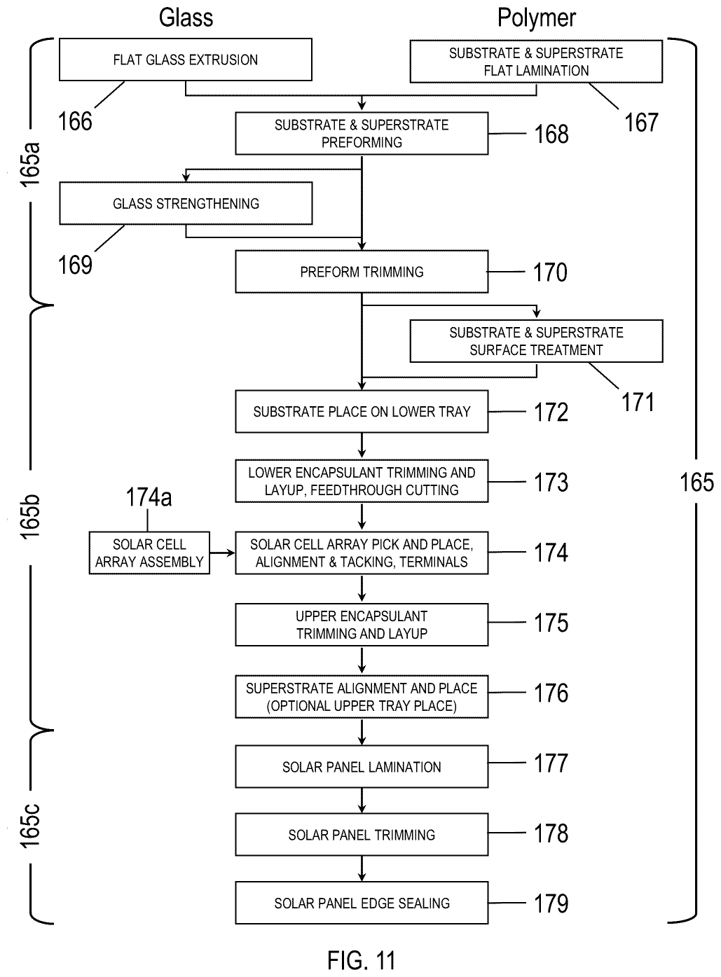

FIG. 11 shows an exemplary method 165 of fabricating a doubly curved solar panel with glass and/or polymer preforms. The method may be divided into three sub-processes: preform fabrication 165a, lamination stack assembly 165b, and lamination/post-processing 165c. In the case of glass substrate and/or superstrate, preform fabrication begins with flat glass extrusion 166. In the case of polymer substrate and/or superstrate, preform fabrication begins with flat lamination 167. In a second step, common to both glass and polymer materials, the substrate and superstrate are shaped into matching preforms 168 using one of the methods tailored to the specific materials, as previously described. For glass preforms, thermal or chemical strengthening 169 follows the shaping step 168. For both types of material, the preforms are precisely trimmed 170 to the final panel dimensions, as by, for example, a laser trimming tool.

The lamination stack assembly process 165b may be considered critical to achieving doubly curved solar panels with high throughput and high yield. Successful double curving of the solar cells may be attributable to the lamination stack, including the choice of materials, elements, forms, placements, alignments, and surface qualities, among other factors. For polymer substrates and/or superstrates the first step may be plasma or corona treatment 171 of the inner-facing surfaces. This step is not necessary for glass surfaces, which readily bond to adhesive polymers such as POE. In the next step 172, common to both glass and polymer materials, the substrate may be placed on a metal tray with a matching shape and a flange that extends beyond the substrate edge. The lower tray may act as a carrier that rides along, or on top of, a conveyor, to convey the lamination stack throughout the assembly process 165b and supports the panel in the subsequent lamination process 165c. The tray may also comprise datums and/or fiducials for the alignment of various layers in the lamination stack. In this embodiment, the tray and substrate may be oriented to present a convex surface when in an upright position. Alternatively, the tray may be configured to hold the lamination stack in an inverted or concave orientation. Next, a lower encapsulant layer may be trimmed and arranged 173 on the substrate. One or more feedthrough openings, or slots, for the solar cell array 200 terminations may be cut through both the substrate and the lower core adhesive layer. The solar cell array may be assembled in a separate process 174a wherein the interconnects, intra-connects, and sub- array terminations may be soldered, or otherwise coupled, to the cells forming a flexible array, as shown in FIG. 3. In the next step 174, a pick and place tool may grab the array 200 from a flat surface, align the same, and place the same on the convex curved lower encapsulant. In this embodiment, the array 200 may be placed 174 on the lamination stack solar-side up, which may require a 180° flip from the soldering/assembly process 174a orientation prior to placement. Before releasing the array, a tacking operation may be performed so as to retain the positions of the cells during subsequent assembly and lamination processes. The sub-array terminations may then be inserted into the feedthroughs and retained on the underside of the panel. Subsequently, the upper encapsulant layer may be trimmed and arranged 175 on the solar cell array. The superstrate is then aligned and placed 176 on the upper encapsulant layer. An optional upper tray is placed on the superstrate. If present, the upper tray may act as a pressure spreader for the lamination step.

The lamination/post-processing steps 165c include the lamination 177, post lamination trimming 178 and edge sealing 179. The lamination may be carried out in a variety of laminators configured to supply vacuum, heat, and pressure independently, in combination and with the proper sequencing and timing, as desired. The lamination stack may be conveyed and loaded into the lamination chamber either manually or robotically and run through the lamination cycle 177. After the lamination 177 is complete, it may be necessary to trim excess encapsulant 178 from the edge of the panel. This may be done mechanically or robotically, such as with a laser trimmer. A clean edge is essential for the ensuing edge sealing operation 179, which can entail molding and/or assembling of edge seal components. At this point, the solar panel is ready for junction box assembly and testing.

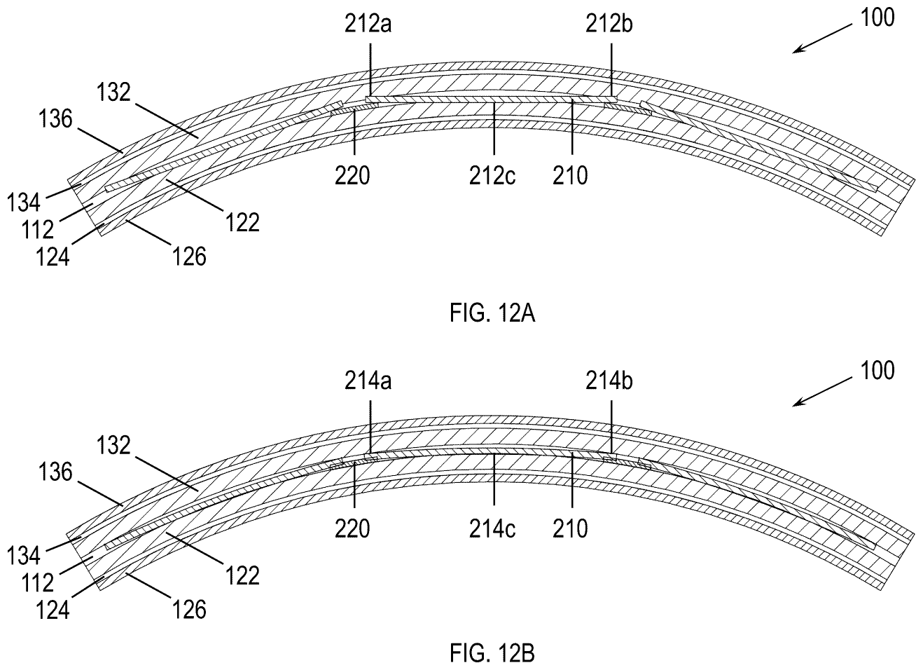

Referring to FIGS. 12A-12B, the solar panel 100 includes solar cells 210 forming solar array 200, wherein the solar cells 210 may be of any suitable type or manufacture that achieves one or more of the problems solved by the present invention. Solar cells 210 may be of the semi-flexible, interdigitated, back-contact (IBC) cell type, available from multiple vendors, such as Maxeon Solar Technologies, Ltd. which produces the Maxeon® Gen III (3) flexible solar cell or SPIC Xi'an Solar Power Co., Ltd. which produces the Zebra M6 flexible solar cell. Other IBC cell vendors include Valoe Corporation. Problems solved by the invention may include yield loss in manufacturing, or field failure of a cell or array of cells, due to the brittleness associated with the solar cell, which principally manifests as the formation and propagation of cracks in the crystalline structure. Such a cell may be made of silicon, gallium arsenide, or any other material suitable for the intended purposes herein.

The bendability of a solar cell is inversely proportional to its thickness. As solar cells have become thinner, bendability has increased. Modern solar cells have a typical thickness of 0.15±0.03 mm and may bow up to 30 mm center to edge along one axis. In general, good bendability may be achieved at a thickness of 0.4 mm or less. Such solar cells have been available commercially since the late 1990s. Insufficient bendability or overbending of a solar cell may result in a micro- or macro-crack in the crystalline material. Microcracks, also known as micro-fractures, are tiny cracks in solar cells that can be invisible to the naked eye. They are a result of a combination of the thin and brittle silicon wafers used to make solar cells and the high stresses in the doubly curved solar panel fabrication process. A microcrack in a solar cell may either reduce that cell's power output, or, in most instances, preclude the solar cell from producing power entirely. By extension, a solar cell having a microcrack may reduce or extinguish the power producing capability of a string or array of cells. Additional flexing can cause microcracks to grow which can lead to macrocracks wherein the cell fails catastrophically, usually including shattering of the silicon.

In addition to Si wafer thickness, it has been demonstrated experimentally that the initiation of cracks in mono and polycrystalline Si solar cells can be traced to uncontrolled alloying of Al into the photocarrier generation portion thereof. Alloying of Al and Si is described by the Al/Si phase diagram which is well known in the art. The most salient points of the Al/Si phase diagram are the melting points of Al and Si, which are 660 and 1414° C., respectively, and the eutectic point which occurs at 12.6 wt. % Si and 577±1° C. The Al/Si eutectic is known to form large, faceted grains in crystalline Si (c-Si). These grains may form spikes which penetrate the underlying Si and leave pits behind when removed. Spiking and pitting, which are complementary aspects of the same phenomenon, are known reliability hazards for Si solar cells which can degrade the yield, efficiency and lifetime of the cells. These grains produce a large tensile strain of approximately −21.7% relative to the c-Si substrate. Crystalline materials, such as Si, commonly have reduced fracture strength when in tension as compared to compression. As a result, tensile stress along with the sharp grains of the eutectic combine to create crack nucleation sites. Cracks will appear when a bending-induced stress and the eutectic-induced stress combine to exceed the fracture strength of the material. Typically, these crack nucleation sites are observed along the alloyed Al busbars of aluminum back surface field (Al-BSF) or passivated emitter and rear contact (PERC) cells. These Al busbars are often applied in ribbon form and connect all of the electrodes on one side of the cell together. Al ribbon busbars also serve as interconnects in strings and arrays of solar cells.

In order to avoid uncontrolled alloying of Al into c-Si, several approaches may be used. They include: 1) using an AlSi alloy with ≤2% Si instead of pure Al, 2) providing a sacrificial layer, such as amorphous Si, that may form an alloy at a lower temperature than the standard eutectic and be self-limiting, 3) providing a barrier layer that is not breached by Al or its alloys, 4) limiting the amount of Al that may react to form an alloy (e.g. using only a thin Al layer), 5) sintering or annealing the Al at a temperature below the alloying (eutectic) temperature (i.e. non-alloying), and 6) avoiding the use of Al altogether.

IBC cells replace front and backside electrodes with interdigitated electrodes formed on a single side of the substrate. Since both n and p-type collectors are formed on the same side of the substrate and must be kept separate, the use of busbars is precluded. Thus, the structure of IBC cells inherently avoids the problems associated with uncontrolled alloying of Al ribbon busbars. IBC cells, however, may use any of the other techniques listed above to incorporate Al into the contact metal stack and may include separate, doped poly-Si emitter layers into which the Al is alloyed. In this way, IBC cells may include some Al but avoid uncontrolled alloying of Al into the c-Si substrate and its attendant yield, performance, and reliability hazards. More importantly for this disclosure, the absence of Al in the Si substrate allows for greater mechanical bendability and a non-catastrophic failure mode wherein microcracks may form but the cell remains intact and continues to produce power. It is these latter two benefits that allow for successful realization of doubly curved solar cells in a doubly curved solar panel.

Several types of backside metallization dominate the solar cell industry. For Al-BSF and PERC cells, a uniform layer of Al paste is screen printed either directly on the Si wafer (Al-BSF) or over a patterned dielectric with openings to the Si wafer (PERC). After drying and firing, the Al not only forms a conductive contact, but also a p+ region in the Si wafer which provides an internal electric field, the so-called “backside field,” which prevents carriers from reaching and recombining at the backside interface, thereby improving efficiency. Spike formation may be suppressed by the inclusion of a small amount of silicon in the aluminum paste, typically 1%.

In an IBC cell, by contrast, both n and p-type emitters are located on the back side of the cell and laid out in an interdigitated fashion. The n and p-type emitters are formed either in the crystalline portion of the Si wafer via dopant diffusion, or by deposition of doped polysilicon layers. A metallization stack is then deposited on the emitters with the goal of creating low-resistance, Ohmic contacts. In general, the metallization stack includes two parts: an adhesion/seed layer and a contact metal. The adhesion/seed layer is generally thin and may act as a passivation layer, an adhesion layer, an Ohmic contact layer, a diffusion barrier layer and/or a plating seed layer.

In one embodiment, a thin SiNx layer and a thin amorphous Si (a-Si) layer are deposited on the emitter. The SiNx layer provides surface passivation of the underlying Si. SiNx readily adheres to the underlying Si, while a-Si readily adheres to SiNx and the subsequently printed Al paste. Openings in the SiNx allow for direct contact between the underlying emitter portion and the a-Si. Alloying may be performed at a temperature below the eutectic temperature because a-Si alloys with Al at a lower temperature than c-Si. In this case the a-Si acts as a sacrificial layer, becoming locally absorbed into the Al paste and forming an alloy (typically ≤2% Si) thereby raising the liquidus temperature and freezing. This is a self-limiting process that avoids Al spiking and at the same time forms a good Ohmic contact. In this embodiment, conductivity and solderability may be improved by plating Ni and/or Cu over the Al layer.

In another embodiment, the metal seed layer can include one, two or more layers. In an example, the metal seed layer can include a first Cu layer, a second W layer and a third Al layer. The Al portion of the metal seed layer may contact the emitter portions of the backside directly. In this case alloying is controlled by including a few wt % Si in the Al film or, alternatively, making the Al layer very thin thereby limiting the eutectic grain size (spikes) that may form. In addition to Cu, W and Al, seed layer metals may include, Ti, Ta, Ni, Nb, Pt, Pd, Au, Ag, Mo, Mg, Mn, Cr, or Zn, among others.

The contact metal layer can include one, two or more layers. In an example, the contact metal layer can include a first Ni layer and a second Cu layer. The contact layer is usually deposited via the plating method. The plating method may be of the electroplating or electroless plating type. In addition to Ni and Cu contact layer metals may include, Al, Sn, Cr, Pd, Pt, Au, Ag, and Rh, among others. In some embodiments, a conductive contact layer includes a metal foil. In a specific example, the metal foil is an Al foil having a thickness approximately in the range of 5-100 microns. Alternatively, the Al foil is an aluminum alloy foil including aluminum and a second element such as, but not limited to, Cu, Mn, Si, Mg, An, Sn, Li, or combinations thereof. The Al foil may be a temper grade foil such as, but not limited to, F-grade (as fabricated), O-grade (full soft), FI-grade (strain hardened) or T-grade (heat treated). The aluminum foil may or may not be anodized.

In the present disclosure, bending of the solar panel 100 may occur in two directions, either synclastically or anticlastically, and be of sufficient curvature to cause the solar cells 210 to bend in two directions as well. FIGS. 12A-12B detail the interaction between the curved layers of the laminated solar panel 100 and the individual solar cells 210. In general, the silicon solar cell 210 is made thin enough (typically around 0.15 mm) to flex in one dimension (typically around 10-30 mm), but to a much lesser extent in two dimensions. Flexing of the solar cells 210 in two dimensions may result in fracture of the material, whether it is single crystal, polycrystalline, or amorphous. Material fracture may reduce or destroy the solar collection efficiency of a cell 210, and, by extension, an array 200, resulting in manufacturing yield loss and higher production cost. FIG. 12A illustrates the case of a flat cell 210 laminated into a curved panel 100. If the cell 210 remains flat it will interfere with the lower, stiff PC layer 122 at point 212c, and the upper, stiff PC layer 132 at the corners of the cell 212a, 212b. Therefore, the cells 210 must bend, as shown in FIG. 12B. However, the radius of curvature of the cells, R_{c}, does not have to perfectly match the radius of curvature of the panel, Rₚ. During the lamination process the encapsulant material surrounding the cell 210, in this case POE 112, is chosen to flow such that the cells 210 will bend only as much as necessary to comply with the stiff lower 122 and upper 132 layers of the panel 100, resulting in compliance points on the bottom center 214c and top corners 214a, 214b of the cell 210. Nevertheless, additional solar cell bending may be required if the encapsulant does not soften completely and allow the solar cells to fully relax. In either case, the primary mechanism by which 2-axis solar panel 100 bending is accommodated by the solar cells 210 is that the cells retain a much larger radius of curvature than the panel. The minimum panel radius of curvature, R_{p_min}, at or above which the solar cells may remain flat, and below which they must bend, is a function of the cell width, w, and thickness, t, and the thickness of the encapsulant polymer layer 112, d, and is given as:

$${R}_{{p}_{-} min} = \frac{{t}^{2} + {( w / 2 )}^{2}}{2 ( d - t )}$$

For example, for a typical solar cell with a long (diagonal) axis of 160 mm and a thickness of 0.15 mm, and for an encapsulant thickness of 1 mm, R_{p_min}=3.76 meters. If Rₚ for any portion of the panel is less than this value in two orthogonal directions, then the solar cell disposed therein must bend in both directions simultaneously. Advantageously, the raised corners of the cell 214a, 214b provide clearance for the interconnect 220 disposed beneath the edges of the cell 210.

Several factors enable the two-axis deformation of the solar cells 210 displayed in FIGS. 12A and 12B. First, the thickness of the encapsulant POE layer 112 of the core 110 allows for a reduced amount of bending of the cell 210 relative to the panel, thereby reducing the stress on the cell 210 and the probability of crack formation, as discussed above. A second contributing factor is the thickness of the c-Si wafer, which should be below 0.4 mm. A third contributing factor is the absence of Al in the Si substrate, which allows an additional amount of flexing of the silicon without catastrophic damage. A fourth contributing factor may be that the two-preform lamination process provides advantages for bending the solar cells 210. During the lamination, the core layers undergo a controlled and uniform deformation to take the shape of the preforms 120, 130. This may be contrasted with other lamination methods in which the lamination force is initially concentrated at a corner or along an edge of one or more cells. In this embodiment, the distance between the substrate and superstrate preforms 120, 130 and the solar cells 200 is well defined and well controlled, which advantageously achieves the desired effect: upon application of the lamination pressure, all cells 210 experience a uniform local pressure simultaneously, resulting in a well-controlled and reproducible deformation, thereby avoiding cell fracture.

The previous description of the disclosed embodiments is provided to enable any person skilled in the art to make or use the invention. Various modifications to these embodiments will be readily apparent to those skilled in the art, and the generic principles defined herein can be applied to other embodiments without departing from the spirit or scope of the invention. It is therefore desired that the present embodiments be considered in all respects as illustrative and not restrictive, reference being made to the appended claims as well as the foregoing descriptions to indicate the scope of the invention.

What is claimed is:

1. A solar panel comprising:
a substrate and a superstrate each including one or more preformed layers, said substrate and superstrate being preformed in a complementary shape when said solar panel is in an assembled configuration; and
a core disposed therebetween, said core comprising a solar cell array including at least one solar cell, said solar cell array being encapsulated by one or more encapsulant layers, said at least one solar cell including a mono- or poly-crystalline silicon wafer having a thickness less than about 0.4 mm and being substantially free of aluminum alloys;
wherein in said assembled configuration, said core is integrally formed with said substrate and said superstrate such that said at least one solar cell of said solar cell array is curved along two orthogonal axes.

2. The solar panel according to claim 1, wherein said one or more preformed layers of said substrate and said superstrate comprise preformed and thermally or chemically strengthened glass.

3. The solar panel according to claim 1, wherein said one or more preformed layers of said substrate and said superstrate comprise preformed layers that have been laminated and thermoformed.

4. The solar panel according to claim 1, wherein said assembled configuration comprises said substrate, said core, and said superstrate that have undergone a lamination process.

5. The solar panel according to claim 4, wherein said lamination process applies substantially uniform pressure across the at least one solar cell of the solar cell array curved along two orthogonal axes.

6. The solar panel according to claim 5, wherein said substantially uniform pressure comprises applying pressure so that said substrate initially moves said at least one cell at a downward-facing side center, and said superstrate simultaneously moves said at least one cell at upward-facing side corners, thereby bending said at least one cell by applying said substantially uniform pressure.

7. The solar panel according to claim 1, wherein either or both of said substrate and said superstrate comprise at least one rigid layer.

8. The solar panel according to claim 7, wherein either or both of said substrate and said superstrate comprise at least one rigid layer and at least one adhesive layer.

9. The solar panel according to claim 8, wherein either or both of said substrate and said superstrate comprise an outer protective layer, an inner rigid layer and one adhesive layer disposed therebetween.

10. The solar panel according to claim 9, wherein said inner rigid layer is a material selected from the group consisting of: polycarbonate (PC), glass, polypropylene (PP), polymethyl methacrylate (PMMA), polyethylene terephthalate (PET), polyvinylchloride (PVC), polyethylene (PE), cyclic olefin copolymer (COC), and fluorinated ethylene propylene (FEP).

11. The solar panel according to claim 9, wherein said outer protective layer is a material selected from the group consisting of: ethylene tetrafluoroethylene (ETFE), glass, and ethylene chlorotrifluoroethylene (ECTFE).

12. The solar panel according to claim 9, wherein said adhesive layer is a material selected from the group consisting of: acrylic-based or silicone-based adhesive transfer tape.

13. The solar panel according to claim 9, wherein said inner rigid layer is a material having an elastic modulus ranging from about 1.79 GPa to about 3.24 GPa.

14. The solar panel according to claim 9, wherein said outer protective layer is a material having an elastic modulus ranging from about from about 0.490 GPa to about 0.827 GPa.

15. A solar panel comprising:
a substrate and a superstrate each including one or more preformed layers, said substrate and superstrate being preformed in a complementary shape when said solar panel is in an assembled configuration; and
a core disposed therebetween, said core comprising a solar cell array including at least one solar cell, said solar cell array being encapsulated by one or more encapsulant layers, said at least one solar cell having an interdigitated, back-contact electrode layer, said back-contact electrode layer selected from the group consisting of: a copper, a tin-coated copper metal grid, and/or other copper metal alloys thereof, and including a silicon wafer having a thickness less than about 0.40 mm and greater than about 0.12 mm,
wherein in said assembled configuration, said core is integrally formed with said substrate and said superstrate such that said at least one solar cell of said solar cell array is curved along two orthogonal axes.

16. A solar panel comprising:
a substrate and a superstrate each including one or more preformed layers, said substrate and superstrate being preformed in a complementary shape when said solar panel is in an assembled configuration; and
a core disposed therebetween, said core comprising a solar cell array including at least one solar cell, said solar cell array being encapsulated by one or more encapsulant layers, said at least one solar cell having an interdigitated, back-contact electrode layer, said back-contact electrode layer selected from the group consisting of: a copper, a tin-coated copper metal grid, and/or other copper metal alloys thereof, and including a wafer having a thickness ranging from about 0.12 mm to about 0.18 mm;
wherein in said assembled configuration, said core is integrally formed with said substrate and said superstrate such that said at least one solar cell of said solar cell array is curved along two orthogonal axes.
